(19) United States
(12) Patent Application Publication
(10) Pub. No.: US 2024/0409810 A1
(43) Pub. Date: Dec. 12, 2024

(54) SEMICONDUCTOR FILM, PHOTODETECTION ELEMENT, IMAGE SENSOR, AND MANUFACTURING METHOD FOR SEMICONDUCTOR QUANTUM DOT

(71) Applicant: FUJIFILM Corporation, Tokyo (JP)

(72) Inventors: Masashi ONO, Shizuoka (JP); Masahiro TAKATA, Shizuoka (JP)

(73) Assignee: FUJIFILM Corporation, Tokyo (JP)

(21) Appl. No.: 18/809,259

(22) Filed: Aug. 19, 2024

Related U.S. Application Data
(63) Continuation of application No. PCT/JP2023/006668, filed on Feb. 24, 2023.

(30) Foreign Application Priority Data
Mar. 7, 2022 (JP) 2022-034164

(51) Int. Cl. C09K 11/75; B82Y 20/00; B82Y 40/00; H10K 30/35

(52) U.S. Cl. CPC C09K 11/755; C09K 11/751; B82Y 20/00; B82Y 40/00; H10K 30/35

(57) ABSTRACT

There is provided a semiconductor film containing an aggregate of semiconductor quantum dots that contain an In element and a Group 15 element and a ligand that is coordinated to the semiconductor quantum dot, in which the Group 15 element includes an Sb element, and a ratio of the number of the In elements to the number of the Group 15 elements in the semiconductor quantum dot is 1.1 or more. There are also provided a photodetection element, an image sensor, and a manufacturing method for a semiconductor quantum dot.

### CROSS-REFERENCE TO RELATED APPLICATIONS

This application is a Continuation of PCT International Application No. PCT/JP2023/006668 filed on Feb. 24, 2023, which claims priority under 35 U.S.C § 119(a) to Japanese Patent Application No. 2022-034164 filed on Mar. 7, 2022. Each of the above application(s) is hereby expressly incorporated by reference, in its entirety, into the present application.

### BACKGROUND OF THE INVENTION

### 1. Field of the Invention

The present invention relates to a semiconductor film containing a semiconductor quantum dot. In addition, the present invention relates to a photodetection element, an image sensor, and a manufacturing method for a semiconductor quantum dot.

### 2. Description of the Related Art

In recent years, attention has been focused on photodetection elements capable of detecting light in the infrared region in the fields such as smartphones, surveillance cameras, and in-vehicle cameras.

In the related art, a silicon photodiode in which a silicon wafer is used as a material of a photoelectric conversion layer has been used in a photodetection element that is used for an image sensor or the like. However, a silicon photodiode has low sensitivity in the infrared region having a wavelength of 900 nm or more.

In addition, an InGaAs-based semiconductor material known as a near-infrared light-receiving element has a problem in that it requires extremely high-cost processes such as epitaxial growth or a step of sticking a substrate in order to realize a high quantum efficiency, and thus it has not been widespread.

In addition, in recent years, the use of the quantum dot for a photoelectric conversion element has been also being studied. For example, JP2020-150251A describes that a PbS quantum dot is used for a photoelectric conversion layer of a photoelectric conversion element.

### SUMMARY OF THE INVENTION

In recent years, with the demand for performance improvement of an image sensor and the like, there is a demand for further improvement of various characteristics that are required in a photodetection element used in the image sensor and the like. For example, one of the characteristics required for the photodetection element is to have a high external quantum efficiency with respect to light having a target wavelength to be detected by the photodetection element, and to have a small in-plane variation in the external quantum efficiency of the photodetection element. In a case of increasing the external quantum efficiency of the photodetection element, it is possible to increase the accuracy of detecting light in the photodetection element. In addition, in a case where the in-plane variation in the external quantum efficiency of the photodetection element is suppressed, the occurrence of noise and the like can be suppressed.

As a result of carrying out studies on a photodetection element in which semiconductor quantum dots containing an In element and a Group 15 element are used for a photoelectric conversion layer, the inventors of the present invention found that there is room for further improvement in these characteristics.

Therefore, an object of the present invention is to provide a semiconductor film having a high external quantum efficiency and excellent in-plane uniformity of the external quantum efficiency. In addition, another object of the present invention is to provide a photodetection element, an image sensor, and a manufacturing method for a semiconductor quantum dot.

The present invention provides the following aspects.

<1> A semiconductor film comprising:
an aggregate of semiconductor quantum dots that contain an In element and a Group 15 element; and
a ligand that is coordinated to the semiconductor quantum dot,
in which the Group 15 element includes an Sb element, and
a ratio of the number of the In elements to the number of the Group 15 elements in the semiconductor quantum dot is 1.1 or more.

<2> The semiconductor film according to <1>, in which the ratio of the number of the In elements to the number of the Group 15 elements in the semiconductor quantum dot is 1.5 or more.

<3> The semiconductor film according to <1>, in which the ratio of the number of the In elements to the number of the Group 15 elements in the semiconductor quantum dot is 2.0 or more.

<4> The semiconductor film according to any one of <1> to <3>, in which the ligand includes an inorganic ligand.

<5> The semiconductor film according to <4>, in which the inorganic ligand includes an inorganic ligand containing a halogen element.

<6> The semiconductor film according to <4>, in which the inorganic ligand includes an inorganic ligand containing an In element.

<7> The semiconductor film according to any one of <1> to <6>, in which a band gap of the semiconductor quantum dot is 1.0 eV or less.

<8> A photodetection element comprising:
the semiconductor film according to any one of <1> to <7>.

<9> An image sensor comprising:
the photodetection element according to <8>.

<10> A manufacturing method for a semiconductor quantum dot, the semiconductor quantum dot containing an In element and a Group 15 element, where the Group 15 element includes an Sb element, and a ratio of the number of the In elements to the number of the Group 15 elements in the semiconductor quantum dot is 1.1 or more, the manufacturing method for a quantum dot film, comprising:
a step of heating, at 290° C. or lower for 16 minutes or more, a precursor solution that contains a compound A containing an In element and a compound B containing an Sb element, where a molar ratio of the In element to the Sb element is 2.1 or more.

According to the present invention, it is possible to provide a semiconductor film having a high external quantum efficiency and excellent in-plane uniformity of external quantum efficiency. In addition, the present invention makes it possible to provide a photodetection element, an image sensor, and a manufacturing method for a semiconductor quantum dot.

### BRIEF DESCRIPTION OF THE DRAWINGS

FIG. 1 is a view illustrating an embodiment of a photodetection element.

### DESCRIPTION OF THE PREFERRED EMBODIMENTS

Hereinafter, the contents of the present invention will be described in detail.

In the present specification, “to” is used to mean that numerical values described before and after “to” are included as a lower limit value and an upper limit value, respectively.

In describing a group (an atomic group) in the present specification, in a case where a description of substitution and non-substitution is not provided, the description means the group includes a group (an atomic group) having a substituent as well as a group (an atomic group) having no substituent. For example, the “alkyl group” includes not only an alkyl group that does not have a substituent (an unsubstituted alkyl group) but also an alkyl group that has a substituent (a substituted alkyl group).

### <Semiconductor Film>

A semiconductor film according to an embodiment of the present invention is characterized by being a semiconductor film containing an aggregate of semiconductor quantum dots that contain an In element and a Group 15 element and a ligand that is coordinated to the semiconductor quantum dot described above, in which the Group 15 element includes an Sb element, and a ratio of the number of the In elements to the number of the Group 15 elements in the above-described semiconductor quantum dot is 1.1 or more.

The semiconductor film according to the embodiment of the present invention has a high external quantum efficiency and excellent in-plane uniformity of external quantum efficiency. The details of the reason why such effects are obtained are unknown; however, it is presumed to be due to the following points.

The external quantum efficiency of the semiconductor film can be improved presumably because the surface of the semiconductor quantum dots is in an In-rich state due to the fact that the ratio of the number of the In elements to the number of the Group 15 elements in the semiconductor quantum dot is 1.1 or more, and thus the ligand binding density in the synthesis or dispersion liquid stage is improved, which improves the morphology controllability or dispersibility of the semiconductor quantum dots. In addition, the in-plane uniformity of the external quantum efficiency of the semiconductor film can be improved presumably because in a case where a dispersion liquid containing semiconductor quantum dots is applied to form a semiconductor film, the application property of the dispersion liquid is good since the dispersibility of the semiconductor quantum dots is also good, which also makes it possible to form a semiconductor film in which the semiconductor quantum dots are almost uniformly dispersed.

The semiconductor film according to the embodiment of the present invention can be used for a photodetection element or an image sensor. More specifically, the semiconductor film can be used for a photoelectric conversion layer of a photodetection element or an image sensor. Therefore, the semiconductor film according to the embodiment of the present invention is preferably used as a photoelectric conversion layer of a photodetection element or an image sensor.

Since the semiconductor film according to the embodiment of the present invention has excellent sensitivity to light having a wavelength in the infrared range, an image sensor in which the semiconductor film according to the embodiment of the present invention is used for a photoelectric conversion layer can be particularly preferably used as an infrared sensor. Therefore, the semiconductor film according to the embodiment of the present invention is preferably used as a dispersion liquid for a photoelectric conversion layer of an infrared sensor.

The thickness of the semiconductor film is not particularly limited; however, it is preferably 10 to 1,000 nm from the viewpoint of obtaining high electrical conductivity. The lower limit of the thickness is preferably 20 nm or more and more preferably 30 nm or more. The upper limit of the thickness is preferably 600 nm or less, more preferably 550 nm or less, still more preferably 500 nm or less, and particularly preferably 450 nm or less.

Hereinafter, the details of the semiconductor film according to the embodiment of the present invention will be described.

### (Aggregate of Semiconductor Quantum Dots Containing in Element and Group 15 Element)

The semiconductor film according to the embodiment of the present invention has an aggregate of semiconductor quantum dots containing an In element and a Group 15 element. The Group 15 element in the semiconductor quantum dot includes an Sb element. It is noted that the aggregate of semiconductor quantum dots means a form in which a large number of semiconductor quantum dots (for example, 100 or more quantum dots per 1 μm²) are arranged to be close to each other. In addition, in the present specification, the “semiconductor” means a substance having a specific resistance value of 10⁻² Ωcm or more and 10⁸ Ωcm or less.

Examples of the semiconductor quantum dot material constituting the semiconductor quantum dot include a compound semiconductor containing an In element and a Group 15 element. It is noted that the compound semiconductor is a semiconductor composed of two or more kinds of elements. Therefore, in the present specification, the “compound semiconductor containing an In element and a Group 15 element” is a compound semiconductor containing an In element and a Group 15 element as elements constituting the compound semiconductor.

In the semiconductor quantum dot, a ratio of the number of the In elements to the number of the Group 15 elements is 1.1 or more, and it is preferably 1.5 or more, and more preferably 2.0 or more. The upper limit thereof is preferably 3.0 or less.

In the present specification, the value of the ratio of the number of the In elements to the number of the Group 15 elements in the semiconductor quantum dot can be calculated by measuring the elemental compositional ratio of the semiconductor quantum dot according to the X-ray photoelectron spectroscopy. For example, it can be obtained by forming a film using a dispersion liquid of semiconductor quantum dots, subjecting this film to the measurement of the elemental compositional ratio of the semiconductor quantum dots by X-ray photoelectron spectroscopy, and carrying out the calculation.

Examples of the method of setting the ratio of the number of the In elements to the number of the Group 15 elements to 1.1 or more for the semiconductor quantum dot include (1) a method of adjusting a mixing ratio of a compound A containing an In element to a compound B containing an Sb element in the synthesis of the semiconductor quantum dot (for example, setting a molar ratio of the In element to the Sb element to 2.1 or more), (2) a method of controlling an adding amount or injection rate of a reducing agent (a dioctyl ether of lithium triethylborohydride) in the synthesis of the semiconductor quantum dot, and (3) a method of controlling a temperature profile such as a reaching temperature, a keep time, and a temperature rising rate in a reaction.

The semiconductor quantum dot may further contain an element other than the In element and the Sb element. Examples of other elements include an Mg element, a Ca element, an Sr element, a Ba element, a Zn element, a Cd element, an Hg element, a B element, an Al element, a Ga element, an N element, a P element, an As element, and a Bi element, and a Zn element, an Al element, a Ga element, a P element, an As element, and a Bi element are preferable.

The crystal structure of the semiconductor quantum dot is not particularly limited. Various crystal structures can be adopted depending on the kind of the element and the compositional ratio of the element constituting the semiconductor quantum dot. However, a crystal structure of a cubic crystal system or hexagonal system is preferable due to the reason that it is easy to properly control a band gap as a semiconductor and it is easy to realize high crystallinity. In a case where the ratio of pure InSb is large in terms of the entire particles, a zinc blende structure is preferable due to the reason that high crystallinity is easily realized. The crystal structure of the semiconductor quantum dot can be measured by an X-ray diffraction method or an electron diffraction method.

The band gap of the semiconductor quantum dot is preferably 1.2 eV or less and more preferably 1.0 eV or less. The lower limit value of the band gap of the semiconductor quantum dot is not particularly limited; however, it is preferably 0.3 eV or more and more preferably 0.5 eV or more.

The average particle diameter of the semiconductor quantum dots is preferably 3 to 20 nm. The lower limit value of the average particle diameter of the semiconductor quantum dots is preferably 4 nm or more and more preferably 5 nm or more. The upper limit value of the average particle diameter of the semiconductor quantum dots is preferably 15 nm or less and more preferably 10 nm or less. In a case where the average particle diameter of the semiconductor quantum dots is in the above-described range, it is possible for the photodetection element to have a higher external quantum efficiency with respect to light having a wavelength in the infrared range. It is noted that in the present specification, the value of the average particle diameter of the semiconductor quantum dots is an average value of the particle diameters of ten semiconductor quantum dots which are randomly selected. A transmission electron microscope may be used for measuring the particle diameter of the semiconductor quantum dots.

### (Ligand)

The semiconductor film according to the embodiment of the present invention contains a ligand that is coordinated to the semiconductor quantum dot. Examples of the ligand include an organic ligand and an inorganic ligand. Due to the reason that it is possible to obtain a semiconductor film having a higher external quantum efficiency and more excellent in-plane uniformity of the external quantum efficiency, it is preferable that the ligand includes an inorganic ligand.

The organic ligand may be a monodentate organic ligand having one coordination moiety or may be a multidentate organic ligand having two or more coordination moieties. Examples of the coordination moiety contained in the organic ligand include a thiol group, an amino group, a hydroxy group, a carboxy group, a sulfo group, a phospho group, and a phosphonate group.

Examples of the multidentate ligand include a ligand represented by any of Formulae (A) to (C).

X^{A1}-L^{A1}-X^{A2} (A)

X^{B1}-L^{B1}-X^{B3}-L^{B2}-X^{B2} (B)

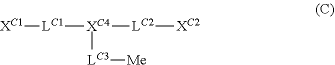

In Formula (A), X^{A1} and X^{A2} each independently represent a thiol group, an amino group, a hydroxy group, a carboxy group, a sulfo group, a phospho group, or a phosphonate group, and L^{A1} represents a hydrocarbon group.

In Formula (B), X^{B1} and X^{B2} each independently represent a thiol group, an amino group, a hydroxy group, a carboxy group, a sulfo group, a phospho group, or a phosphonate group, X^{B3} represents S, O, or NH, and L^{B1} and L^{B2} each independently represent a hydrocarbon group.

In Formula (C), X^{C1} to X^{C3} each independently represent a thiol group, an amino group, a hydroxy group, a carboxy group, a sulfo group, a phospho group, or a phosphonate group, X^{C4} represents N, and L^{C1} to L^{C3} each independently represent a hydrocarbon group.

The amino group represented by X^{A1}, X^{A2}, X^{B1}, X^{B2}, X^{C1}, X^{C2}, or X^{C3} is not limited to —NH₂ and includes a substituted amino group and a cyclic amino group as well. Examples of the substituted amino group include a monoalkylamino group, a dialkylamino group, a monoarylamino group, a diarylamino group, and an alkylarylamino group. The amino group represented by these groups is preferably —NH₂, a monoalkylamino group, or a dialkylamino group, and more preferably —NH₂.

The hydrocarbon group represented by L^{A1}, L^{B1}, L^{B2}, L^{C1}, L^{C2}, or L^{C3} is preferably an aliphatic hydrocarbon group or a group including an aromatic ring and more preferably an aliphatic hydrocarbon group. The aliphatic hydrocarbon group may be a saturated aliphatic hydrocarbon group or may be an unsaturated aliphatic hydrocarbon group. The hydrocarbon group preferably has 1 to 20 carbon atoms. The upper limit of the number of carbon atoms is preferably 10 or less, more preferably 6 or less, and still more preferably 3 or less. Specific examples of the hydrocarbon group include an alkylene group, an alkenylene group, an alkynylene group, and an arylene group.

Examples of the alkylene group include a linear alkylene group, a branched alkylene group, and a cyclic alkylene group. A linear alkylene group or a branched alkylene group is preferable, and a linear alkylene group is more preferable. Examples of the alkenylene group include a linear alkenylene group, a branched alkenylene group, and a cyclic alkenylene group. A linear alkenylene group or a branched alkenylene group is preferable, and a linear alkenylene group is more preferable. Examples of the alkynylene group include a linear alkynylene group and a branched alkynylene group, and a linear alkynylene group is preferable. The arylene group may be monocyclic or may be polycyclic. The monocyclic arylene group is preferable. Specific examples of the arylene group include a phenylene group and a naphthylene group. Among these, a phenylene group is preferable. The alkylene group, the alkenylene group, the alkynylene group, and the arylene group may further have a substituent. The substituent is preferably a group having 1 or more and 10 or less of atoms. Preferred specific examples of the group having 1 or more and 10 or less of atoms include an alkyl group having 1 to 3 carbon atoms [a methyl group, an ethyl group, a propyl group, or an isopropyl group], an alkenyl group having 2 or 3 carbon atoms [an ethenyl group or a propenyl group], an alkynyl group having 2 to 4 carbon atoms [an ethynyl group, a propynyl group, or the like], a cyclopropyl group, an alkoxy group having 1 or 2 carbon atoms [a methoxy group or an ethoxy group], an acyl group having 2 or 3 carbon atoms [an acetyl group or a propionyl group], an alkoxycarbonyl group having 2 or 3 carbon atoms [a methoxycarbonyl group or an ethoxycarbonyl group], an acyloxy group having 2 carbon atoms [an acetyloxy group], an acylamino group having 2 carbon atoms [an acetylamino group], a hydroxyalkyl group having 1 to 3 carbon atoms [a hydroxymethyl group, a hydroxyethyl group, or a hydroxypropyl group], an aldehyde group, a hydroxy group, a carboxy group, a sulfo group, a phospho group, a carbamoyl group, a cyano group, an isocyanate group, a thiol group, a nitro group, a nitroxy group, an isothiocyanate group, a cyanate group, a thiocyanate group, an acetoxy group, an acetamide group, a formyl group, a formyloxy group, a formamide group, a sulfamino group, a sulfino group, a sulfamoyl group, a phosphono group, an acetyl group, a halogen atom, and an alkali metal atom.

In Formula (A), X^{A1} and X^{A2} are separated by L^{A1} preferably by 1 to 10 atoms, more preferably separated by 1 to 6 atoms, still more preferably separated by 1 to 4 atoms, even still more preferably separated by 1 to 3 atoms, and particularly preferably separated by 1 or 2 atoms.

In Formula (B), X^{B1} and X^{B3} are separated by L^{B1} preferably by 1 to 10 atoms, more preferably separated by 1 to 6 atoms, still more preferably separated by 1 to 4 atoms, even still more preferably separated by 1 to 3 atoms, and particularly preferably separated by 1 or 2 atoms. In addition, X^{B2} and X^{B3} are separated by L^{B2} preferably by 1 to 10 atoms, more preferably separated by 1 to 6 atoms, still more preferably separated by 1 to 4 atoms, even still more preferably separated by 1 to 3 atoms, and particularly preferably separated by 1 or 2 atoms.

In Formula (C), X^{C1} and X^{C4} are separated by L^{C1} preferably by 1 to 10 atoms, more preferably separated by 1 to 6 atoms, still more preferably separated by 1 to 4 atoms, even still more preferably separated by 1 to 3 atoms, and particularly preferably separated by 1 or 2 atoms. In addition, X^{C2} and X^{C4} are separated by L^{C2} preferably by 1 to 10 atoms, more preferably separated by 1 to 6 atoms, still more preferably separated by 1 to 4 atoms, even still more preferably separated by 1 to 3 atoms, and particularly preferably separated by 1 or 2 atoms. In addition, X^{C3} and X^{C4} are separated by L^{C3} preferably by 1 to 10 atoms, more preferably separated by 1 to 6 atoms, still more preferably separated by 1 to 4 atoms, even still more preferably separated by 1 to 3 atoms, and particularly preferably separated by 1 or 2 atoms.

It is noted that the description that X^{A1} and X^{A2} are separated by L^{A1} by 1 to 10 atoms means that the number of atoms constituting a molecular chain having the shortest distance, connecting X^{A1} and X^{A2}, is 1 to 10 atoms. For example, in a case of Formula (A1), X^{A1} and X^{A2} are separated by two atoms, and in cases of Formulae (A2) and (A3), X^{A1} and X^{A2} are separated by 3 atoms. The numbers added to the following structural formulae represent the arrangement order of atoms constituting a molecular chain having the shortest distance, connecting X^{A1} and X^{A2}.

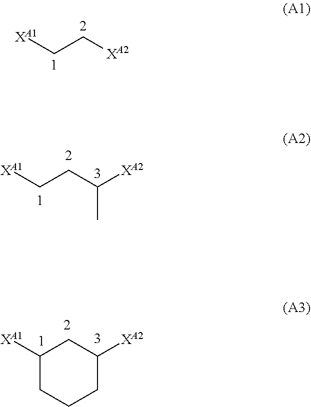

To make a description with a specific compound, 3-mercaptopropionic acid is a compound (a compound having the following structure) having a structure in which a moiety corresponding to X^{A1} is a carboxy group, a moiety corresponding to X^{A2} is a thiol group, and a moiety corresponding to L^{A1} is an ethylene group. In 3-mercaptopropionic acid, X^{A1} (the carboxy group) and X^{A2} (the thiol group) are separated by L^{A1} (the ethylene group) by two atoms.

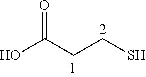

The same applies to the meanings that X^{B1} and X^{B3} are separated by L^{B1} by 1 to 10 atoms, X^{B2} and X^{B3} are separated by L^{B2} by 1 to 10 atoms, X^{C1} and X^{C4} are separated by L^{C1} by 1 to 10 atoms, X^{C2} and X^{C4} are separated by L^{C2} by 1 to 10 atoms, and X^{C3} and X^{C4} are separated by L^{C3} by 1 to 10 atoms.

Specific examples of the multidentate ligand include 3-mercaptopropionic acid, thioglycolic acid, 2-aminoethanol, 2-aminoethanethiol, 2-mercaptoethanol, glycolic acid, ethylene glycol, ethylenediamine, aminosulfonic acid, glycine, aminomethylphosphoric acid, guanidine, diethylenetriamine, tris(2-aminoethyl)amine, 4-mercaptobutanoic acid, 3-aminopropanol, 3-mercaptopropanol, N-(3-aminopropyl)-1,3-propanediamine, 3-(bis(3-aminopropyl)amino)propan-1-ol, 1-thioglycerol, dimercaprol, 1-mercapto-2-butanol, 1-mercapto-2-pentanol, 3-mercapto-1-propanol, 2,3-dimercapto-1-propanol, diethanolamine, 2-(2-aminoethyl)aminoethanol, dimethylenetriamine, 1,1-oxybismethylamine, 1,1-thiobismethylamine, 2-[(2-aminoethyl)amino]ethanethiol, bis(2-mercaptoethyl)amine, 2-aminoethane-1-thiol, 1-amino-2-butanol, 1-amino-2-pentanol, L-cysteine, D-cysteine, 3-amino-1-propanol, L-homoserine, D-homoserine, aminohydroxyacetic acid, L-lactic acid, D-lactic acid, L-malic acid, D-malic acid, glyceric acid, 2-hydroxybutyric acid, L-tartaric acid, D-tartaric acid, tartronic acid, 1,2-benzenedithiol, 1,3-benzenedithiol, 1,4-benzenedithiol, 2-mercaptobenzoic acid, 3-mercaptobenzoic acid, 4-mercaptobenzoic acid, and derivatives thereof.

The inorganic ligand is preferably an inorganic ligand containing a halogen element. The inorganic ligand containing a halogen element is easily coordinated to the semiconductor quantum dot and can suppress the generation of surface defects.

The inorganic ligand is also preferably an inorganic ligand containing an In element. In particular, in a case where the semiconductor quantum dot is such one that has InSb as a mother crystal, it is considered that the inorganic ligand containing an In element is easily coordinated to the Sb site of the semiconductor quantum dot, and thus the generation of surface defects can be further suppressed.

Due to the reason that it is possible to obtain a semiconductor film having a higher external quantum efficiency and more excellent in-plane uniformity of the external quantum efficiency, the semiconductor film preferably contains an inorganic ligand containing a halogen element and an In element, respectively.

Examples of the halogen element contained in the inorganic ligand include a fluorine element, a chlorine element, a bromine element, and an iodine element, and a bromine element is preferable.

Specific examples of the inorganic ligand include zinc iodide, zinc bromide, zinc chloride, indium iodide, indium bromide, indium chloride, cadmium iodide, cadmium bromide, cadmium chloride, gallium iodide, gallium bromide, gallium chloride, tetrabutylammonium iodide, tetramethylammonium iodide, and ammonium sulfide, and indium bromide is preferable.

It is noted that in the inorganic ligand containing a halogen element, the halogen ion may be dissociated from the inorganic ligand described above, and the halogen ion may be coordinated on the surface of the semiconductor quantum dot. In addition, a moiety of the inorganic ligand other than the halogen atom described above may also be coordinated to the surface of the semiconductor quantum dot. To make a description with a case of indium bromide a specific example, the indium bromide may be coordinated to the surface of the semiconductor quantum dot, or the bromide ion or the indium ion may be coordinated to the surface of the semiconductor quantum dot.

### <Manufacturing Method for Semiconductor Quantum Dot>

A manufacturing method for a semiconductor quantum dot according to an embodiment of the present invention is characterized by being a manufacturing method for a semiconductor quantum dot, where the semiconductor quantum dot contains an In element and a Group 15 element, the Group 15 element includes an Sb element, a ratio of the number of the In elements to the number of the Group 15 elements in the semiconductor quantum dot is 1.1 or more, and the manufacturing method for a quantum dot film includes a step of heating, at 290° C. or lower for 16 minutes or more, a precursor solution that contains a compound A (hereinafter also referred to as an In compound) containing an In element and a compound B (hereinafter also referred to as an Sb compound) containing an Sb element, where a molar ratio of the In element to the Sb element is 2.1 or more.

In the precursor solution, the molar ratio (In element/Sb element) of the In element to the Sb element is 2.1 or more, and it is preferably 2.2 or more and more preferably 2.4 or more. The upper limit thereof is preferably 4.0 or less and more preferably 3.0 or less.

The In compound contained in the above-described precursor solution is not particularly limited as long as it is a compound containing an In element, and examples thereof include indium chloride, indium acetate, indium oxide, and indium nitrate. The Sb compound contained in the above-described precursor solution is not particularly limited as long as it is a compound containing an Sb element, and examples thereof include antimony chloride, antimony acetate, antimony oxide, and antimony nitrate.

The above-described precursor solution is heated to react the In compound with the Sb compound, thereby manufacturing the semiconductor quantum dots.

The heating temperature is 290° C. or lower, and it is preferably 285° C. or lower and more preferably 280° C. or lower. In a case where the heating temperature is 290° C. or lower, the particles are unlikely to aggregate, and thus the uniformity of the particles can be promoted. The lower limit of the heating temperature is preferably 200° C. or higher and more preferably 240° C. or higher.

The heating time is 16 minutes or more, and it is preferably 18 minutes or more, more preferably 20 minutes or more, and still more preferably 25 minutes or more. The upper limit of the heating time is preferably 60 minutes or less and more preferably 30 minutes or less.

It is preferable that the reaction between the In compound and the Sb compound is carried out in the presence of a reducing agent. That is, it is preferable that the precursor solution further contains a reducing agent. According to this aspect, particles having high crystallinity are easily formed. Examples of the reducing agent include lithium triethylborohydride.

In a case where the reaction between the In compound and the Sb compound is carried out in the presence of a reducing agent, the adding amount of the reducing agent is preferably 2.0 to 8.0 mol, more preferably 3.0 to 6.0 mol, and still more preferably 4.0 to 5.0 mol with respect to 1 mol of the In compound.

In this way, it is possible to manufacture semiconductor quantum dots which are semiconductor quantum dot containing an In element and a Group 15 element and in which the Group 15 element includes an Sb element, and a ratio of the number of the In elements to the number of the Group 15 elements in the semiconductor quantum dot is 1.1 or more.

In the semiconductor quantum dot, a ratio of the number of the In elements to the number of the Group 15 elements is preferably 1.5 or more, and more preferably 2.0 or more. The upper limit thereof is preferably 3 or less.

### <Manufacturing Method for Semiconductor Film>

The semiconductor film according to the embodiment of the present invention can be formed through a step (a semiconductor quantum dot aggregate forming step) of applying a dispersion liquid (hereinafter, also referred to as a semiconductor quantum dot dispersion liquid) containing the above-described semiconductor quantum dots, a ligand, and a solvent onto a substrate to form a film of aggregates of the semiconductor quantum dots.

The content of the quantum dot in the quantum dot dispersion liquid is preferably 1 to 500 mg/mL, more preferably 10 to 200 mg/mL, and still more preferably 20 to 100 mg/mL.

Examples of the ligand contained in the quantum dot dispersion liquid include the organic ligand and the inorganic ligand which are described above.

In addition, the ligand contained in the quantum dot dispersion liquid acts as a ligand that is coordinated to the quantum dot and concurrently has a molecular structure that easily causes steric hindrance, and thus it is also preferable that the ligand also serves as a dispersing agent that disperses semiconductor quantum dots in the solvent. Such a ligand is preferably a ligand having at least 6 or more carbon atoms in the main chain and is more preferably a ligand having 10 or more carbon atoms in the main chain. The ligand may be a saturated compound or may be any unsaturated compound. Specific examples thereof include decanoic acid, lauric acid, myristic acid, palmitic acid, stearic acid, behenic acid, oleic acid, erucic acid, oleylamine, stearylamine, 1-aminodecane, dodecylamine, aniline, dodecanethiol, 1,2-hexadecanethiol, tributylphosphine, trihexylphosphine, trioctylphosphine, tributylphosphine oxide, trioctylphosphine oxide, and cetrimonium bromide.

The content of the ligand in the quantum dot dispersion liquid is preferably 0.1 mmol/L to 500 mmol/L and more preferably 0.5 mmol/L to 100 mmol/L.

The solvent contained in the semiconductor quantum dot dispersion liquid is not particularly limited; however, it is preferably a solvent that hardly dissolves the semiconductor quantum dots and easily dissolves the ligand. The solvent is preferably an organic solvent. Specific examples thereof include alkanes (n-hexane, n-octane, and the like), alkenes (octadecene and the like), benzene, and toluene. The solvent contained in the quantum dot dispersion liquid may be only one kind or may be a mixed solvent in which two or more kinds are mixed.

The content of the solvent in the quantum dot dispersion liquid is preferably 50% to 99% by mass, more preferably 70% to 99% by mass, and still more preferably 90% to 98% by mass.

The semiconductor quantum dot dispersion liquid may further contain other components as long as the effects of the present invention are not impaired.

The shape, structure, size, and the like of the substrate onto which the quantum dot dispersion liquid is applied are not particularly limited, and the substrate can be appropriately selected according to the intended purpose. The structure of the substrate may be a monolayer structure or a laminated structure. As the substrate, for example, a substrate composed of an inorganic material such as such, glass, or yttria-stabilized zirconia (YSZ), a resin, a resin composite material, or the like can be used. In addition, an electrode, an insulating film, or the like may be formed on the substrate. In this case, the dispersion liquid is also applied onto the electrode or the insulating film on the substrate.

The method of applying a quantum dot dispersion liquid onto a substrate is not particularly limited. Examples thereof include coating methods such as a spin coating method, a dipping method, an ink jet method, a dispenser method, a screen printing method, a relief printing method, an intaglio printing method, and a spray coating method.

The film thickness of the film of aggregates of the semiconductor quantum dots, formed by the semiconductor quantum dot aggregate forming step, is preferably 3 nm or more, more preferably 10 nm or more, and still more preferably 20 nm or more. The upper limit thereof is preferably 200 nm or less, more preferably 150 nm or less, and still more preferably 100 nm or less.

After forming a film of aggregates of the semiconductor quantum dots, a ligand exchange step may be further carried out to exchange the ligand coordinated to the semiconductor quantum dot with another ligand. It is preferable that in the ligand exchange step, a ligand solution containing a ligand (hereinafter, also referred to as a ligand A) different from the ligand contained in the above-described quantum dot dispersion liquid and containing a solvent is applied onto the film of aggregates of the semiconductor quantum dots, the aggregates being formed by the semiconductor quantum dot aggregate forming step, to exchange the ligand coordinated to the semiconductor quantum dots with the ligand A contained in the ligand solution. In addition, the semiconductor quantum dot aggregate forming step and the ligand exchange step may be alternately repeated a plurality of times.

Examples of the ligand A include the organic ligand and the inorganic ligand which are described above.

The ligand solution that is used in the ligand exchange step may contain only one kind of the ligand A or may contain two or more kinds thereof. In addition, two or more kinds of ligand solutions may be used.

The solvent contained in the ligand solution is preferably selected appropriately according to the kind of the ligand contained in each ligand solution, and it is preferably a solvent that easily dissolves each ligand. In addition, the solvent contained in the ligand solution is preferably an organic solvent having a high dielectric constant. Specific examples thereof include ethanol, acetone, methanol, acetonitrile, dimethylformamide, dimethyl sulfoxide, butanol, and propanol. In addition, the solvent contained in the ligand solution is preferably a solvent that does not easily remain in the formed semiconductor film. From the viewpoints of easy drying and easy removal by washing, a low boiling point alcohol, a ketone, or a nitrile is preferable, and methanol, ethanol, acetone, or acetonitrile is more preferable. The solvent contained in the ligand solution is preferably one that does not mix with the solvent contained in the quantum dot dispersion liquid. Regarding the preferred solvent combination, in a case where the solvent contained in the quantum dot dispersion liquid is an alkane such as hexane or octane or toluene, it is preferable to use a polar solvent such as methanol or acetone as the solvent contained in the ligand solution.

A step (a rinsing step) of bringing a rinsing liquid into contact with a film after the ligand exchange step to rinse the film may be carried out. In a case where the rinsing step is carried out, it is possible to remove the excessive ligand contained in the semiconductor film and the ligand eliminated from the semiconductor quantum dots. In addition, the rinsing step may be carried out a plurality of times by using two or more kinds of rinsing liquids differing in polarity (relative permittivity). For example, it is preferable that, first, a rinsing liquid (also referred to as a first rinsing liquid) having a high relative permittivity is used to carry out rinsing, and then a rinsing liquid (also referred to as a second rinsing liquid) having a relative permittivity lower than that of the first rinsing liquid is used to carry out rinsing. In a case of rinsing in this way, it is possible to first remove the excess component of the ligand A used in the ligand exchange, and then remove the eliminated ligand component (the component that has been originally coordinated to the particles) generated in the ligand exchange process, and it is possible to more efficiently remove both the excess or the eliminated ligand component. The relative permittivity of the first rinsing liquid is preferably 15 to 50, more preferably 20 to 45, and still more preferably 25 to 40. The relative permittivity of the second rinsing liquid is preferably 1 to 15, more preferably 1 to 10, and still more preferably 1 to 5.

The manufacturing method for a semiconductor film may include a drying step. In a case of carrying out the drying step, it is possible to remove the solvent remaining on the semiconductor film. The drying time is preferably 1 to 100 hours, more preferably 1 to 50 hours, and still more preferably 5 to 30 hours. The drying temperature is preferably 10° C. to 100° C., more preferably 20° C. to 90° C., and still more preferably 20° C. to 60° C. The drying step may be carried out in an atmosphere containing oxygen or may be carried out in a nitrogen atmosphere. The amount of the residual solvent contained in the semiconductor film is preferably 5% by mass or less, more preferably 3% by mass or less, and still more preferably 1% by mass or less with respect to the total amount of the semiconductor film. The lower limit may thereof be, for example, 0.0001% by mass. The semiconductor film may contain water, and it is preferably 5% by mass or less, more preferably 3% by mass or less, and still more preferably 1% by mass or less with respect to the total amount of the semiconductor film. The lower limit may thereof be, for example, 0.0001% by mass. In the manufacturing step of the semiconductor film, the semiconductor quantum dot and the ligand may be oxidized.

### <Photodetection Element>

The photodetection element according to the embodiment of the present invention includes the above-described semiconductor film according to the embodiment of the present invention. Preferably, the photodetection element includes the semiconductor film according to the embodiment of the present invention as a photoelectric conversion layer of the photodetection element.

Examples of the type of photodetection element include a photoconductor-type photodetection element and a photodiode-type photodetection element. Among the above, a photodiode-type photodetection element is preferable due to the reason that a high signal-to-noise ratio (SN ratio) is easily obtained.

Since the semiconductor film according to the embodiment of the present invention has excellent sensitivity to the light having a wavelength in the infrared range, a photodetection element in which this semiconductor film is used for a photoelectric conversion layer is preferably used as a photodetection element that detects light having a wavelength in the infrared range. That is, the photodetection element is preferably used as an infrared photodetection element.

The light having a wavelength in the infrared range is preferably light having a wavelength of more than 700 nm, more preferably light having a wavelength of 800 nm or more, and still more preferably light having a wavelength of 900 nm or more. In addition, the light having a wavelength in the infrared range is preferably light having a wavelength of 3,000 nm or less, more preferably light having a wavelength of 2,000 nm or less, and still more preferably light having a wavelength of 1,600 nm or less.

The photodetection element may be a photodetection element that simultaneously detects light having a wavelength in the infrared range and light having a wavelength in the visible region (preferably light having a wavelength in a range of 400 to 700 nm).

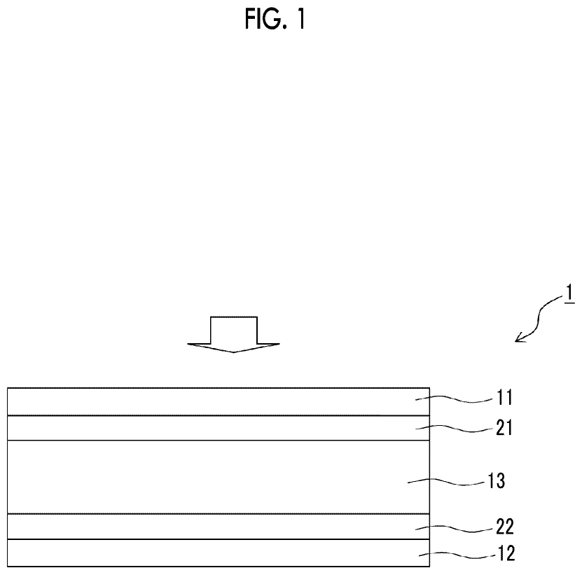

FIG. 1 is a diagram illustrating an embodiment of a photodetection element. FIG. 1 is a view illustrating an embodiment of a photodiode-type photodetection element. It is noted that an arrow in the FIGURE represents the incidence ray on the photodetection element. A photodetection element 1 illustrated in FIG. 1 includes a second electrode layer 12, a first electrode layer 11 provided to be opposite to the second electrode layer 12, a photoelectric conversion layer 13 provided between the second electrode layer 12 and the first electrode layer 11, an electron transport layer 21 provided between the first electrode layer 11 and the photoelectric conversion layer 13, and a hole transport layer 22 provided between the second electrode layer 12 and the photoelectric conversion layer 13. The photodetection element 1 illustrated in FIG. 1 is used by causing light to be incident from above the first electrode layer 11. Although not illustrated in the drawing, a transparent substrate may be disposed on the surface of the first electrode layer 11 on the light incident side. Examples of the kind of transparent substrate include a glass substrate, a resin substrate, and a ceramic substrate.

### (First Electrode Layer)

The first electrode layer 11 is preferably a transparent electrode formed of a conductive material that is substantially transparent with respect to the wavelength of the target light to be detected by the photodetection element. It is noted that in the present specification, the description of “substantially transparent” means that the light transmittance is 50% or more, preferably 60% or more, and particularly preferably 80% or more. Examples of the material of the first electrode layer 11 include a conductive metal oxide. Specific examples thereof include tin oxide, zinc oxide, indium oxide, indium tungsten oxide, indium zinc oxide (IZO), indium tin oxide (ITO), and a fluorine-doped tin oxide (FTO).

The film thickness of the first electrode layer 11 is not particularly limited, and it is preferably 0.01 to 100 μm, more preferably 0.01 to 10 μm, and particularly preferably 0.01 to 1 μm. The film thickness of each layer can be measured by observing the cross section of the photodetection element 1 using a scanning electron microscope (SEM) or the like.

### (Electron Transport Layer)

The electron transport layer 21 is a layer having a function of transporting electrons generated in the photoelectric conversion layer 13 to the electrode layer. The electron transport layer is also called a hole block layer. The electron transport layer is formed of an electron transport material that is capable of exhibiting this function.

Examples of the electron transport material include a fullerene compound such as [6,6]-phenyl-C61-butyric acid methyl ester (PC61BM), a perylene compound such as perylenetetracarboxylic diimide, tetracyanoquinodimethane, titanium oxide, tin oxide, zinc oxide, indium oxide, indium tungsten oxide, indium zinc oxide, indium tin oxide, and fluorine-doped tin oxide. The electron transport material may be a particle.

In addition, it is also preferable that the electron transport layer is composed of a layer containing zinc oxide doped with a metal atom other than Zn. Hereinafter, the zinc oxide doped with a metal atom other than Zn is also referred to as the doped zinc oxide.

The metal atom other than Zn in the doped zinc oxide is preferably a monovalent to trivalent metal atom, more preferably a metal atom including at least one selected from Li, Mg, A1, or Ga, still more preferably Li, Mg, A1, or Ga, and particularly preferably Li or Mg.

In the doped zinc oxide, the proportion of the metal atom other than Zn to the total of Zn and the metal atom other than Zn is preferably 1% by atom or more, more preferably 2% by atom or more, and still more preferably 4% by atom or more. From the viewpoint of suppressing an increase in crystal defects, the upper limit thereof is preferably 20% by atom or less, more preferably 15% by atom or less, and still more preferably 12% by atom or less. It is noted that the proportion of the metal atom other than Zn in the doped zinc oxide can be measured according to a high-frequency inductively coupled plasma (ICP) method.

From the viewpoint of reducing the organic residual component and increasing the area for contact with the photoelectric conversion layer, the doped zinc oxide is preferably a particle (a doped zinc oxide particle). In addition, the average particle diameter of the doped zinc oxide particles is preferably 2 to 30 nm. The lower limit value of the average particle diameter of the doped zinc oxide particles is preferably 3 nm or more and more preferably 5 nm or more. In addition, the upper limit value of the average particle diameter of the doped zinc oxide particles is preferably 20 nm or less and more preferably 15 nm or less. In a case where the average particle diameter of the doped zinc oxide particles is within the above-described range, it is easy to obtain a film that has a large area for contact with the photoelectric conversion layer and has a high flatness. It is noted that in the present specification, the value of the average particle diameter of the doped zinc oxide particles is an average value of the particle diameters of ten quantum dots which are randomly selected. A transmission electron microscope may be used to measure the particle diameter of the doped zinc oxide particles.

The electron transport layer may be a single-layer film or a laminated film having two or more layers. The thickness of the electron transport layer is preferably 10 to 1,000 nm. The upper limit thereof is preferably 800 nm or less. The lower limit thereof is preferably 20 nm or more and more preferably 50 nm or more. In addition, the thickness of the electron transport layer is preferably 0.05 to 10 times, more preferably 0.1 to 5 times, and still more preferably 0.2 to 2 times the thickness of the photoelectric conversion layer 13.

The electron transport layer may be subjected to an ultraviolet ozone treatment. In particular, in a case of a layer consisting of nanoparticles as the electron transport layer, it is desirable to carry out an ultraviolet ozone treatment. In a case where the ultraviolet ozone treatment is carried out, it is possible to improve the wettability of the quantum dot dispersion liquid on the electron transport layer can be improved and decompose or remove the residual organic substances in the electron transport layer, which makes it possible to obtain high element performance. The wavelength of the ultraviolet rays for irradiation can be selected in a wavelength range of 100 to 400 nm. In particular, due to the reason that the above-described effect is easily obtained and excessive damage to a film can be avoided, it is preferable that the peak intensity is present in a wavelength range of 200 to 300 nm, and it is more preferable that the peak intensity is present in a wavelength range of 240 to 270 nm. The irradiation intensity of the ultraviolet rays is not particularly limited; however, it is preferably 1 to 100 mW/cm² and more preferably 10 to 50 mW/cm² due to the reason that the above-described effect is easily obtained and excessive damage to a film can be avoided. The treatment time is not particularly limited; however, it is preferably 1 to 60 minutes, more preferably 1 to 20 minutes, and still more preferably 3 to 15 minutes, for the same reason as described above.

### (Photoelectric Conversion Layer)

The photoelectric conversion layer 13 is composed of the above-described semiconductor film according to the embodiment of the present invention. That is, the photoelectric conversion layer 13 contains an aggregate of semiconductor quantum dots that contain an In element and a Group 15 element and a ligand that is coordinated to the semiconductor quantum dot. The Group 15 element includes an Sb element. In the semiconductor quantum dot, a ratio of the number of the In elements to the number of the Group 15 elements is 1.1 or more, and it is preferably 1.5 or more, and more preferably 2.1 or more.

The thickness of the photoelectric conversion layer 13 is preferably 10 to 1,000 nm. The lower limit of the thickness is preferably 20 nm or more and more preferably 30 nm or more. The upper limit of the thickness is preferably 600 nm or less, more preferably 550 nm or less, still more preferably 500 nm or less, and particularly preferably 450 nm or less. The refractive index of the photoelectric conversion layer 13 with respect to light having a target wavelength to be detected by the photodetection element can be set to 1.5 to 5.0.

### (Hole Transport Layer)

The hole transport layer 22 is a layer having a function of transporting holes generated in the photoelectric conversion layer 13 to the electrode layer. The hole transport layer is also called an electron block layer.

The hole transport layer 22 is formed of a hole transport material capable of exhibiting this function. Examples of the hole transport material include PEDOT:PSS (poly(3,4-ethylenedioxythiophene):poly(4-styrenesulfonic acid)), PTB7 (poly{4,8-bis[(2-ethylhexyl)oxy]benzo[1,2-b:4,5-b′]dithiophen-2,6-diyl-lt-alt-3-fluoro-2-[(2-et hylhexyl)carbonyl]thieno[3,4-b]thiophen-4,6-diyl}), PTB7-Th (poly([2,6′-4,8-di(5-ethylhexylthienyl)benzo[1,2-b:3,3-b′]dithiophen]{3-fluoro-2-[(2-ethylhexyl)1)carbonyl]thieno[3,4-b]thiophendiyl})), PC71BM ([6,6]-phenyl-C71-methyl butyrate), and MoO₃. In addition, the organic hole transport material disclosed in paragraph Nos. 0209 to 0212 of JP2001-291534A can also be used. In addition, a quantum dot can also be used in the hole transport material. Examples of the quantum dot material that constitutes the quantum dot include a nanoparticle (a particle having a size of 0.5 nm or more and less than 100 nm) of a general semiconductor crystal [a) a Group IV semiconductor, b) a compound semiconductor of a Group IV to IV element, a Group III to V element, or a Group II to VI element, or c) a compound semiconductor consisting of a combination of three or more of a Group II element, a Group III element, a Group IV element, a Group V element, and a Group VI element]. Specific examples thereof include semiconductor materials having a relatively narrow band gap, such as PbS, PbSe, PbSeS, InN, Ge, InAs, InGaAs, CuInS, CuInSe, CuInGaSe, InSb, HgTe, HgCdTe, Ag₂S, Ag₂Se, Ag₂Te, SnS, SnSe, SnTe, Si, and InP. A ligand may be coordinated on the surface of the quantum dot.

The thickness of the hole transport layer 22 is preferably 5 to 100 nm. The lower limit thereof is preferably 10 nm or more. The upper limit thereof is preferably 50 nm or less and more preferably 30 nm or less.

### (Second Electrode Layer)

The second electrode layer 12 is preferably composed of a metal material containing at least one metal atom selected from Ag, Au, Pt, Ir, Pd, Cu, Pb, Sn, Zn, Ti, W, Mo, Ta, Ge, Ni, Al, Cr, or In. Since the second electrode layer 12 is composed of such a metal material, it is possible for the photodetection element to have a high external quantum efficiency and a low dark current. In addition, the above-described conductive metal oxide, a carbon material, a conductive polymer, and the like can also be used for the second electrode layer 12. The carbon material may be any material having conductivity, and examples thereof include fullerene, a carbon nanotube, graphite, and graphene.

The work function of the second electrode layer 12 is preferably 4.6 eV or more, more preferably 4.8 to 5.7 eV, and still more preferably 4.9 to 5.3 eV, due to the reason that the electron blocking property due to the hole transport layer is increased and the holes generated in the element are easily collected.

The film thickness of the second electrode layer 12 is not particularly limited, and it is preferably 0.01 to 100 μm, more preferably 0.01 to 10 μm, and particularly preferably 0.01 to 1 μm.

### (Blocking Layer)

Although not illustrated in the drawing, the photodetection element may have a blocking layer between the first electrode layer 11 and the electron transport layer 21. The blocking layer is a layer having a function of preventing a reverse current. The blocking layer is also called a short circuit prevention layer. Examples of the material that forms the blocking layer include silicon oxide, magnesium oxide, aluminum oxide, calcium carbonate, cesium carbonate, polyvinyl alcohol, polyurethane, titanium oxide, tin oxide, zinc oxide, niobium oxide, and tungsten oxide. The blocking layer may be a single-layer film or a laminated film having two or more layers.

In the photodetection element, a wavelength, of the target light to be detected by the photodetection element and an optical path length L of the light having the wavelength, from the surface of the second electrode layer 12 on the side of the photoelectric conversion layer 13 to the surface of the photoelectric conversion layer 13 on the side of the first electrode layer 11 preferably satisfy the relationship of Formula (1-1), and more preferably satisfy the relationship of Formula (1-2). In a case where the wavelength λ and the optical path length L^{λ} satisfy such a relationship, in the photoelectric conversion layer 13, it is possible to arrange phases of the light (the incidence ray) incident from the side of the first electrode layer 11 and phases of the light (the reflected light) reflected on the surface of the second electrode layer 12, and as a result, the light is intensified by the optical interference effect, whereby it is possible to obtain a higher external quantum efficiency.

$$0.05 + m / 2 \leq {L}^{λ} / λ \leq 0.35 + m / 2 \qquad ( 1 - 1 )$$

$$0.1 + m / 2 \leq {L}^{λ} / λ \leq 0.30 + m / 2 \qquad ( 1 - 2 )$$

In the above expressions, λ is the wavelength of the target light to be detected by the photodetection element,
L^{λ} is the optical path length of the light having the wavelength λ from a surface of the second electrode layer 12 on a side of the photoelectric conversion layer 13 to a surface of the photoelectric conversion layer 13 on a side of the first electrode layer 11, and
m is an integer of 0 or more.

m is preferably an integer of 0 to 4, more preferably an integer of 0 to 3, and still more preferably an integer of 0 to 2. According to this aspect, the transport characteristics of charges such as the hole and the electron are good, and thus it is possible to increase the external quantum efficiency of the photodetection element.

Here, the optical path length means the product obtained by multiplying the physical thickness of a substance through which light transmits by the refractive index. To make a description with the photoelectric conversion layer 13 as an example, in a case where the thickness of the photoelectric conversion layer is denoted by d¹ and the refractive index of the photoelectric conversion layer with respect to light having a wavelength λ¹ is denoted by N¹, the optical path length of the light having the wavelength λ¹ and transmitting through the photoelectric conversion layer 13 is N¹×d¹. In a case where the photoelectric conversion layer 13 or the hole transport layer 22 is composed of two or more laminated films or in a case where an interlayer is present between the hole transport layer 22 and the second electrode layer 12, the integrated value of the optical path length of each layer is the optical path length L^{λ}.

### <Image Sensor>

The image sensor according to the embodiment of the present invention includes the above-described photodetection element according to the embodiment of the present invention. This image sensor can be particularly preferably used as an infrared sensor since the photodetection element according to the embodiment of the present invention has excellent sensitivity to light having a wavelength in the infrared range. In addition, the image sensor can be preferably used as a sensor for sensing light having a wavelength of 900 to 3000 nm, can be more preferably used as a sensor for sensing light having a wavelength of 900 to 2,000 nm, and can be still more preferably used as a sensor for sensing light having a wavelength of 900 to 1,600 nm.

The configuration of the image sensor is not particularly limited as long as it has the photodetection element and it is a configuration that functions as an image sensor. Examples of the photodetection element include the above-described photodetection element.

The image sensor invention may include an infrared transmitting filter layer. The infrared transmitting filter layer preferably has a low light transmittance in the wavelength range of the visible region, more preferably has an average light transmittance of 10% or less, still more preferably 7.5% or less, and particularly preferably 5% or less in a wavelength range of 400 to 650 nm.

Examples of the infrared transmitting filter layer include those composed of a resin film containing a coloring material. Examples of the coloring material include a chromatic coloring material such as a red coloring material, a green coloring material, a blue coloring material, a yellow coloring material, a purple coloring material, and an orange coloring material, and a black coloring material. It is preferable that the coloring material contained in the infrared transmitting filter layer forms a black color with a combination of two or more kinds of chromatic coloring materials or is a coloring material containing a black coloring material. Examples of the combination of the chromatic coloring material in a case of forming a black color by a combination of two or more kinds of chromatic coloring materials include the following aspects (C1) to (C7).

(C1) an aspect containing a red coloring material and a blue coloring material.

(C2) an aspect containing a red coloring material, a blue coloring material, and a yellow coloring material.

(C3) an aspect containing a red coloring material, a blue coloring material, a yellow coloring material, and a purple coloring material.

(C4) an aspect containing a red coloring material, a blue coloring material, a yellow coloring material, a purple coloring material, and a green coloring material.

(C5) an aspect containing a red coloring material, a blue coloring material, a yellow coloring material, and a green coloring material.

(C6) an aspect containing a red coloring material, a blue coloring material, and a green coloring material.

(C7) an aspect containing a yellow coloring material and a purple coloring material.

The chromatic coloring material may be a pigment or a dye. It may contain a pigment and a dye. The black coloring material is preferably an organic black coloring material. Examples of the organic black coloring material include a bisbenzofuranone compound, an azomethine compound, a perylene compound, and an azo compound.

The infrared transmitting filter layer may further contain an infrared absorber. In a case where the infrared absorber is contained in the infrared transmitting filter layer, the wavelength of the light to be transmitted can be shifted to the longer wave side. Examples of the infrared absorber include a pyrrolo pyrrole compound, a cyanine compound, a squarylium compound, a phthalocyanine compound, a naphthalocyanine compound, a quaterrylene compound, a merocyanine compound, a croconium compound, an oxonol compound, an iminium compound, a dithiol compound, a triarylmethane compound, a pyrromethene compound, an azomethine compound, an anthraquinone compound, a dibenzofuranone compound, a dithiolene metal complex, a metal oxide, and a metal boride.

The spectral characteristics of the infrared transmitting filter layer can be appropriately selected according to the use application of the image sensor. Examples of the filter layer include those that satisfy any one of the following spectral characteristics of (1) to (5).

(1): A filter layer in which the maximum value of the light transmittance in the film thickness direction in a wavelength range of 400 to 750 nm is 20% or less (preferably 15% or less and more preferably 10% or less), and the minimum value of the light transmittance in the film thickness direction in a wavelength range of 900 to 1,500 nm is 70% or more (preferably 75% or more and more preferably 80% or more).

(2): A filter layer in which the maximum value of the light transmittance in the film thickness direction in a wavelength range of 400 to 830 nm is 20% or less (preferably 15% or less and more preferably 10% or less), and the minimum value of the light transmittance in the film thickness direction in a wavelength range of 1,000 to 1,500 nm is 70% or more (preferably 75% or more and more preferably 80% or more).

(3): A filter layer in which the maximum value of the light transmittance in the film thickness direction in a wavelength range of 400 to 950 nm is 20% or less (preferably 15% or less and more preferably 10% or less), and the minimum value of the light transmittance in the film thickness direction in a wavelength range of 1,100 to 1,500 nm is 70% or more (preferably 75% or more and more preferably 80% or more).

(4): A filter layer in which the maximum value of the light transmittance in the film thickness direction in a wavelength range of 400 to 1,100 nm is 20% or less (preferably 15% or less and more preferably 10% or less), and the minimum value thereof in a wavelength range of 1,400 to 1,500 nm is 70% or more (preferably 75% or more and more preferably 80% or more).

(5): A filter layer in which the maximum value of the light transmittance in the film thickness direction in a wavelength range of 400 to 1,300 nm is 20% or less (preferably 15% or less and more preferably 10% or less), and the minimum value thereof in a wavelength range of 1,600 to 2,000 nm is 70% or more (preferably 75% or more and more preferably 80% or more).

Further, as the infrared transmitting filter, the films disclosed in JP2013-077009A, JP2014-130173A, JP2014-130338A, WO2015/166779A, WO2016/178346A, WO2016/190162A, WO2018/016232A, JP2016-177079A, JP2014-130332A, and WO2016/027798A can be used. As the infrared transmitting filter, two or more filters may be used in combination, or a dual bandpass filter that transmits through two or more specific wavelength ranges with one filter may be used.

The image sensor may include an infrared shielding filter for the intended purpose of improving various performances such as noise reduction. Specific examples of the infrared shielding filter include the filters disclosed in WO2016/186050A, WO2016/035695A, JP6248945B, WO2019/021767A, JP2017-067963A, and JP6506529B.

The image sensor may include a dielectric multi-layer film. Examples of the dielectric multi-layer film include those in which a plurality of layers are laminated by alternately laminating a dielectric thin film having a high refractive index (a high refractive index material layer) and a dielectric thin film having a low refractive index (a low refractive index material layer). The number of laminated layers of the dielectric thin film in the dielectric multi-layer film is not particularly limited; however, it is preferably 2 to 100 layers, more preferably 4 to 60 layers, and still more preferably 6 to 40 layers. The material that is used for forming the high refractive index material layer is preferably a material having a refractive index of 1.7 to 2.5. Specific examples thereof include Sb₂O₃, Sb₂S₃, Bi₂O₃, CeO₂, CeF₃, HfO₂, La₂O₃, Nd₂O₃, Pr₆O₁₁, Sc₂O₃, SiO, Ta₂O₅, TiO₂, TlCl, Y₂O₃, ZnSe, ZnS, and ZrO₂. The material that is used for forming the low refractive index material layer is preferably a material having a refractive index of 1.2 to 1.6. Specific examples thereof include Al₂O₃, BiF₃, CaF₂, LaF₃, PbCl₂, PbF₂, LiF, MgF₂, MgO, NdF₃, SiO₂, Si₂O₃, NaF, ThO₂, ThF₄, and Na₃AlF₆. The method for forming the dielectric multi-layer film is not particularly limited; however, examples thereof include ion plating, a vacuum deposition method using an ion beam or the like, a physical vapor deposition method (a PVD method) such as sputtering, and a chemical vapor deposition method (a CVD method). The thickness of each of the high refractive index material layer and the low refractive index material layer is preferably 0.1λ to 0.5λ in a case where the wavelength of the light to be blocked is λ (nm). Specific examples of the usable dielectric multi-layer film include the films disclosed in JP2014-130344A and JP2018-010296A.

In the dielectric multi-layer film, the transmission wavelength range is preferably present in the infrared range (preferably a wavelength range having a wavelength of more than 700 nm, more preferably a wavelength range having a wavelength of more than 800 nm, and still more preferably a wavelength range having a wavelength of more than 900 nm). The maximum transmittance in the transmission wavelength range is preferably 70% or more, more preferably 80% or more, and still more preferably 90% or more. In addition, the maximum transmittance in the shielding wavelength range is preferably 20% or less, more preferably 10% or less, and still more preferably 5% or less. In addition, the average transmittance in the transmission wavelength range is preferably 60% or more, more preferably 70% or more, and still more preferably 80% or more. In addition, in a case where the wavelength at which the maximum transmittance is exhibited is denoted by a central wavelength λₜ₁, the wavelength range of the transmission wavelength range is preferably “the central wavelength λₜ₁±100 nm”, more preferably “the central wavelength λₜ₁±75 nm”, and still more preferably “the central wavelength λₜ₁±50 nm”.

The dielectric multi-layer film may have only one transmission wavelength range (preferably, a transmission wavelength range having a maximum transmittance of 90% or more) or may have a plurality of transmission wavelength ranges.

The image sensor may include a color separation filter layer. Examples of the color separation filter layer include a filter layer including colored pixels. Examples of the kind of colored pixel include a red pixel, a green pixel, a blue pixel, a yellow pixel, a cyan pixel, and a magenta pixel. The color separation filter layer may include colored pixels having two or more colors or having only one color. It can be appropriately selected according to the use application and the intended purpose. For example, the filter disclosed in WO2019/039172A can be used.

In addition, in a case where the color separation layer includes colored pixels having two or more colors, the colored pixels of the respective colors may be adjacent to each other, or a partition wall may be provided between the respective colored pixels. The material of the partition wall is not particularly limited. Examples thereof include an organic material such as a siloxane resin or a fluororesin, and an inorganic particle such as a silica particle. In addition, the partition wall may be composed of a metal such as tungsten or aluminum.

It is noted that in a case where the image sensor includes an infrared transmitting filter layer and a color separation layer, it is preferable that the color separation layer is provided on an optical path different from the infrared transmitting filter layer. In addition, it is also preferable that the infrared transmitting filter layer and the color separation layer are disposed two-dimensionally. It is noted that the description that the infrared transmitting filter layer and the color separation layer are disposed two-dimensionally means that at least parts of both are present on the same plane.

The image sensor may include an interlayer such as a planarizing layer, an underlying layer, or an intimate attachment layer, an anti-reflection film, and a lens. As the anti-reflection film, for example, a film produced from the composition disclosed in WO2019/017280A can be used. As the lens, for example, the structure disclosed in WO2018/092600A can be used.

### EXAMPLES

Hereinafter, the present invention will be described in detail with reference to Examples. Materials, amounts used, proportions, treatment details, treatment procedures, and the like shown in the following examples can be appropriately changed without departing from the gist of the present invention. Accordingly, a scope of the present invention is not limited to the following specific examples.

### [Production of Quantum Dot Dispersion Liquid]

### (Quantum Dot Dispersion Liquid 1)

5 mmol of indium chloride was added to 50 mL of oleylamine in a glove box, and the resultant mixture was heated and stirred at 60° C. to dissolve the indium chloride, thereby preparing a precursor solution A1 (indium concentration: about 0.1 mol/L).

5 mmol of antimony chloride was added to 20 mL of oleylamine in a glove box, and the resultant mixture was heated and stirred at 60° C. to dissolve the antimony chloride, thereby preparing a precursor solution B1 (antimony concentration: about 0.25 mol/L).

In a glove box, 100 mL of a tetrahydrofuran (THF) solution of lithium triethylborohydride (concentration of lithium triethylborohydride: 1.0 mol/L, manufactured by Sigma-Aldrich Co., LLC.) was mixed with 50 mL of dioctyl ether, and THF was distilled off to prepare a solution C1 which is a dioctyl ether solution of lithium triethylborohydride (concentration of lithium triethylborohydride: about 2.0 mol/L).

In a glove box, 16.5 mL of the precursor solution A1, 3 mL of the precursor solution B1, and 13.5 mL of oleylamine were added to a three-neck flask to obtain a mixed solution (indium element/antimony element=1.65/0.75 (molar ratio)). Then, the three-neck flask was taken out from the glove box and repeatedly subjected to vacuuming and nitrogen purging, and then the state thereof was transitioned to a nitrogen flow state. Here, 2.9 mL of the solution C1 was injected into the mixed solution. Then, the temperature was raised to 260° C. at a rate of 3° C./min, and the liquid temperature was maintained for about 20 minutes after reaching 260° C. to form nuclei. Then, the liquid temperature in the flask was cooled to room temperature.

The three-neck flask was put again in the glove box, 6 mL of oleic acid and 90 mL of toluene were added to the obtained quantum dot solution and stirred, and then centrifugal separation was carried out at about 8,000 rpm to remove the precipitate. Then, 60 mL of acetonitrile was added to the supernatant, centrifugal separation was carried out again at 8,000 rpm, and the semiconductor quantum dots (InSb quantum dots 1) which are target particles were precipitated. Then, 9 mL of octane was added to the precipitate to obtain a quantum dot dispersion liquid 1 (a dispersion liquid of the InSb quantum dots 1). A quantum dot thin film was produced using the obtained quantum dot dispersion liquid 1, and as a result of estimating the band gap from the wavelength at which the inflection point of absorption was observed from the absorption measurement of the quantum dot thin film, it was approximately 0.99 eV.

### (Quantum Dot Dispersion Liquid 2)

InSb quantum dots 2 were obtained by the same operation as the operation in the manufacturing step of the quantum dot dispersion liquid 1 to obtain a quantum dot dispersion liquid 2 (a dispersion liquid of the InSb quantum dots 2), except that in a glove box, 18 mL of the precursor solution A1, 3 mL of the precursor solution B1, and 12 mL of oleylamine were added to a three-neck flask to obtain a mixed solution (indium element/antimony element=1.8/0.75 (molar ratio)). A quantum dot thin film was produced using the obtained quantum dot dispersion liquid 2, and as a result of estimating the band gap from the wavelength at which the inflection point of absorption was observed from the absorption measurement of the quantum dot thin film, it was approximately 0.97 eV.

### (Quantum Dot Dispersion Liquid 3)

InSb quantum dots 3 were obtained by the same operation as the operation in the manufacturing step of the quantum dot dispersion liquid 1 to obtain a quantum dot dispersion liquid 3 (a dispersion liquid of the InSb quantum dots 3), except that in a glove box, 19.5 mL of the precursor solution A1, 3 mL of the precursor solution B1, and 10.5 mL of oleylamine were added to a three-neck flask to obtain a mixed solution (indium element/antimony element=1.95/0.75 (molar ratio)). A quantum dot thin film was produced using the obtained quantum dot dispersion liquid 3, and as a result of estimating the band gap from the wavelength at which the inflection point of absorption was observed from the absorption measurement of the quantum dot thin film, it was approximately 0.97 eV.

### (Quantum Dot Dispersion Liquid C-1)

4 mmol of indium chloride was added to 100 mL of oleylamine in a glove box, and the resultant mixture was heated and stirred at 50° C. to dissolve the indium chloride, thereby preparing a precursor solution A2 (indium concentration: about 0.04 mol/L).

5 mmol of antimony chloride was added to 20 mL of oleylamine in a glove box, and the resultant mixture was heated and stirred at 50° C. to dissolve the antimony chloride, thereby preparing a precursor solution B2 (antimony concentration: about 0.25 mol/L).

In a glove box, 10 mL of the precursor solution A2 and 1 mL of the precursor solution B2 were added to a three-neck flask to obtain a mixed solution (indium element/antimony element=0.4/0.25 (molar ratio)). Then, the three-neck flask was taken out from the glove box and repeatedly subjected to vacuuming and nitrogen purging, and then the state thereof was transitioned to a nitrogen flow state. Here, 1.1 mL of the solution C1 was injected into the mixed solution. Then, the temperature was raised to 260° C. at a rate of 3° C./min, and the liquid temperature was maintained for about 15 minutes after reaching 260° C. to form nuclei. The liquid temperature in the flask was cooled to room temperature.

The three-neck flask was put again in the glove box, 6 mL of oleic acid and 90 mL of toluene were added to the obtained quantum dot solution and stirred, and then centrifugal separation was carried out at about 8,000 rpm to remove the precipitate. Then, 60 mL of acetonitrile was added to the supernatant, centrifugal separation was carried out again at 8,000 rpm, and the semiconductor quantum dots (InSb quantum dots C1) which are target particles were precipitated. Then, 9 mL of toluene was added to the precipitate to obtain a quantum dot dispersion liquid C-1 (a dispersion liquid of the InSb quantum dots C1). A quantum dot thin film was produced using the obtained quantum dot dispersion liquid C-1, and as a result of estimating the band gap from the wavelength at which the inflection point of absorption was observed from the absorption measurement of the quantum dot thin film, it was approximately 0.99 eV.

### [Measuring Method for Elemental Compositional Ratio of Semiconductor Quantum Dot]

Using each of the quantum dot dispersion liquids 1 to 3 and C-1, a drop cast film having a thickness of about several m was produced on a silicon substrate coated with Au. Then, using an X-ray photoelectron spectroscopy (XPS) apparatus, the elemental compositional ratio of the semiconductor quantum dot was measured by X-ray photoelectron spectroscopy under the following conditions. In the following table, the ratio of the number of the indium elements to the number of the Group 15 elements is described in the column of “Elemental compositional ratio 1” of the table below, and the ratio of the number of the indium elements to the number of the antimony elements is described in the column of “In/Sb ratio”.

It is noted that the elemental compositional ratio was measured at three points in the same drop cast film, and the average value thereof was calculated as the elemental compositional ratio of the semiconductor quantum dot.
X-ray source: Monochromatized A1-K rays (100 μmf, 25 W, 15 kV)
Measurement region: 300 m×300 m (Area measurement)
Pass Energy: 55 eV
Electrical charge correction: Yes (an electron gun and a low-speed ion gun are used in combination)
Photoelectron extraction angle: 45°

TABLE 1

| | Elemental | |
|---|---|---|
| Kind of semiconductor | compositional | In/Sb |
| quantum dot | ratio 1 | ratio |
| InSb quantum dot 1 | 1.2 | 1.2 |
| InSb quantum dot 2 | 1.6 | 1.6 |
| InSb quantum dot 3 | 2.1 | 2.1 |
| InSb quantum dot C1 | 0.9 | 0.9 |

### [Ligand Exchange of Quantum Dot Dispersion Liquid]

### (Manufacturing of InSb—InBr₃ Dispersion Liquids 1 to 3)

1.8 mL of oleic acid and 54 mL of acetone were added to 9 mL of the quantum dot dispersion liquid described in the table below, and centrifugal separation was carried out at 8,000 G for 5 minutes. Then, the supernatant was removed, and the precipitate was dispersed in octane so that the concentration was 6 mg/mL to obtain a dispersion liquid 1 (concentration of InSb quantum dot: 6 mg/mL).

Separately, 1.8 g of indium bromide (InBr) and 0.23 g of ammonium acetate were added to 50 mL of N,N-dimethylformamide (DMF) and dissolved to obtain a ligand exchange solution.

24 mL of the ligand exchange solution and 16 mL of the dispersion liquid 1 were added to a centrifuge tube, and the resultant mixture was stirred for 2 minutes with a vortex mixer and then allowed to stand until the octane phase (upper layer) and the DMF phase (lower layer) were separated. Next, the octane phase as the upper layer was removed, and 16 mL of octane was added thereto, followed by stirring with a vortex mixer for 2 minutes. Again, the octane phase as the upper layer was removed, and 16 mL of octane was added thereto, followed by stirring with a vortex mixer for 2 minutes. Further, the octane phase as the upper layer was removed, and 48 mL of toluene was added thereto, followed by centrifugal separation at 8,000 G for 5 minutes. Then, the supernatant was removed, and the precipitate was subjected to vacuum drying for 15 minutes and then redispersed in 0.4 mL of DMF to obtain each of quantum dot dispersion liquids (InSb—InBr₃ dispersion liquids 1 to 3) in which InBr₃ was coordinated as a ligand to the semiconductor quantum dot described in the table below.

(Manufacturing of InSb—(NH₄)₂S Dispersion Liquids 1 and 2)

1.8 mL of oleic acid and 54 mL of acetone were added to 9 mL of the quantum dot dispersion liquid described in the table below, and centrifugal separation was carried out at 8,000 rpm for 5 minutes. Then, the supernatant was removed, and the precipitate was dispersed in hexane so that the concentration was 6 mg/mL to obtain a dispersion liquid 2 (concentration of InSb quantum dot: 6 mg/mL).

Separately, 50 mL of formamide was added to 500 μL of an ammonium sulfide aqueous solution (manufactured by Sigma-Aldrich Co., LLC., 40 to 48 wt %) to obtain a ligand exchange solution.

24 mL of the ligand exchange solution and 16 mL of the dispersion liquid 2 were added to a centrifuge tube, and the resultant mixture was stirred for 2 minutes with a vortex mixer and then allowed to stand until the hexane phase (upper layer) and the formamide phase (lower layer) were separated. Next, the hexane phase as the upper layer was removed, and 16 mL of hexane was added thereto, followed by stirring with a vortex mixer for 2 minutes. Again, the hexane phase as the upper layer was removed, and 16 mL of hexane was added thereto, followed by stirring with a vortex mixer for 2 minutes. Further, the hexane phase as the upper layer was removed, 48 mL of acetonitrile was added thereto, and centrifugal separation was carried out at 8,000 rpm for 5 minutes. Then, the supernatant was removed, and redispersion was carried out in 0.4 mL of DMF to obtain each of quantum dot dispersion liquids (InSb—(NH₄)₂S dispersion liquids 1 and 2) in which (NH₄)₂S was coordinated as a ligand to the semiconductor quantum dot described in the table below.

### (Manufacturing of InSb—Na₂S Dispersion Liquid 1)

70 μL of a formamide solution of 15 mg/mL of Na₂S and 30 μL of formamide were added to 100 μL of the quantum dot dispersion liquid C-1 in which the concentration of the InSb quantum dots C1 was adjusted to 15 mg/mL. The resultant mixture was stirred with a vortex mixer for about 5 minutes until all the InSb quantum dots C1 were completely transitioned to the formamide phase. Next, the toluene layer as the upper layer was removed. Then, 100 μL of toluene was further added thereto, the mixture was stirred for 1 minute with a vortex mixer, and organic ligands that were liberated or weakly bonded were removed (a step 1).

After repeating the step 1 again, 100 μL of acetonitrile was added thereto, centrifugal separation was carried out at 6,000 rpm for 2 minutes, and then the supernatant was removed. Then, the precipitate of the quantum dots was redispersed in 50 μL of DMF to obtain a quantum dot dispersion liquid (InSb—Na₂S dispersion liquid 1) in which Na₂S was coordinated as a ligand to the semiconductor quantum dot described in the table below.

TABLE 2

| | Kind of quantum dot | Kind of semiconductor | Kind |
|---|---|---|---|
| | dispersion liquid | quantum dot | of ligand |
| InSb—InBr₃ dispersion liquid 1 | Quantum dot dispersion liquid 1 | InSb quantum dot 1 | InBr₃ |
| InSb—InBr dispersion liquid 2 | Quantum dot dispersion liquid 2 | InSb quantum dot 2 | InBr₃ |
| InSb—InBr dispersion liquid 3 | Quantum dot dispersion liquid 3 | InSb quantum dot 3 | InBr₃ |
| InSb—(NH₄)₂S dispersion liquid 1 | Quantum dot dispersion liquid 1 | InSb quantum dot 1 | (NH₄)₂S |
| InSb—(NH₄)₂S dispersion liquid 2 | Quantum dot dispersion liquid C-1 | InSb quantum dot C1 | (NH₄)₂S |
| InSb—Na₂S dispersion liquid 1 | Quantum dot dispersion liquid C-1 | InSb quantum dot C1 | Na₂S |

### [Manufacturing of Zinc Oxide Particle Dispersion Liquid]

1.5 mmol of zinc acetate dihydrate and 15 mL of dimethyl sulfoxide (DMSO) were measured and put in a flask, stirred, and dissolved to obtain a zinc acetate solution.

A TMACl solution obtained by dissolving 4 mmol of tetramethylammonium chloride (TMACl) in 4 ml of methanol and a KOH solution obtained by dissolving 4 mmol of potassium hydroxide (KOH) in 4 mL of methanol were produced. The KOH solution was slowly introduced while vigorously stirring the TMACl solution, and after stirring for 30 minutes, insoluble components were removed through a filter of 0.45 μm to obtain a tetramethylammonium hydroxide (TMAH) solution.

6 mL of the TMHA solution was added to the zinc acetate solution contained in the flask at a dropwise addition rate of 6 mL/min. After being held for 1 hour, the reaction solution was recovered. An excessive amount of acetone was added to the reaction solution, centrifugal separation was carried out at 10,000 rpm for 10 minutes. Then, the supernatant was removed, and the precipitate was dispersed in methanol. Then, the precipitate was precipitated again with acetone, 5 mL of ethanol and 80 μL of aminoethanol were added thereto, and ultrasonic dispersion was carried out to obtain a zinc oxide particle dispersion liquid in which the concentration of the non-doped zinc oxide particles was 30 mg/mL.

### [Manufacturing of Photodetection Element]

### Example 1

An indium tin oxide (ITO) film (the first electrode layer) having a thickness of about 100 nm was formed on quartz glass by a sputtering method.

Next, the first electrode layer was subjected to spin coating with a solution obtained by dissolving 1 g of zinc acetate dihydrate and 284 μL of ethanolamine in 10 mL of methoxyethanol at 3,000 rpm. Then, heating was carried out at 200° C. for 30 minutes to form a zinc oxide film (an electron transport layer) having a thickness of about 40 nm.

Next, a step of dropwise adding the above-described zinc oxide particle dispersion liquid onto the electron transport layer and subsequently carrying out spin coating at 2,500 rpm and heating at 70° C. for 30 minutes was repeated twice to obtain a zinc oxide particle film having a film thickness of about 130 nm. After forming the zinc oxide particle film, an ultraviolet ozone treatment was carried out for 5 minutes under a condition of 30 mW/cm² (wavelength peak: 254 nm) using UVO-CLEANER MODEL 144AX-100 manufactured by Jelight Company Inc.

Next, the zinc oxide lamination layer was subjected to spin coating at 5,000 rpm with the InSb—InBr₃ dispersion liquid 1 to obtain an InSb quantum dot film (photoelectric conversion layer) having a thickness of about 130 nm.

Next, a MoO3 film having a thickness of 10 nm was formed on the photoelectric conversion layer by a vacuum deposition method through a metal mask, and then an Au film (second electrode layer) having a thickness of 100 nm was formed to form three element parts, thereby manufacturing a photodiode-type photodetection element.

### Example 2

A photodetection element of Example 2 was manufactured in the same method as in Example 1, except that in the step of forming the photoelectric conversion film, the InSb—InBr₃ dispersion liquid 2 was used instead of the InSb—InBr₃ dispersion liquid 1.

### Example 3

A photodetection element of Example 3 was manufactured in the same method as in Example 1, except that in the step of forming the photoelectric conversion film, the InSb—InBr₃ dispersion liquid 3 was used instead of the InSb—InBr₃ dispersion liquid 1.

### Example 4

A photodetection element of Example 4 was manufactured in the same method as in Example 1, except that in the step of forming the photoelectric conversion film, the InSb—(NH₄)₂S 1 was used instead of the InSb—InBr₃ dispersion liquid 1.

### Comparative Example 1

An indium tin oxide (ITO) film (the first electrode layer) having a thickness of about 100 nm was formed on quartz glass by a sputtering method.

Next, the first electrode layer was subjected to spin coating with a solution obtained by dissolving 1 g of zinc acetate dihydrate and 284 μL of ethanolamine in 10 mL of methoxyethanol at 3,000 rpm. Then, heating was carried out at 200° C. for 30 minutes to form a zinc oxide film (an electron transport layer) having a thickness of about 40 nm.

Next, a step of dropwise adding the above-described zinc oxide particle dispersion liquid onto the electron transport layer and subsequently carrying out spin coating at 2,500 rpm and heating at 70° C. for 30 minutes was repeated twice to obtain a zinc oxide particle film having a film thickness of about 130 nm. After forming the zinc oxide particle film, an ultraviolet ozone treatment was carried out for 5 minutes under a condition of 30 mW/cm² (wavelength peak: 254 nm) using UVO-CLEANER MODEL 144AX-100 manufactured by Jelight Company Inc.

Next, the zinc oxide lamination layer was subjected to spin coating with the InSb—Na₂S dispersion liquid 1 at 1,500 rpm for 1 minute to obtain a quantum dot film. A methanol solution of 5 mM of NaN₃ was added dropwise to the obtained quantum dot film, and the quantum dot film was allowed to stand for 10 seconds, and then subjected to spin drying (a step A). Then, methanol rinsing was carried out three times (a step B). Further, the step A and the step B were repeated twice to obtain an InSb quantum dot film (photoelectric conversion layer) having a thickness of about 130 nm.

Next, a MoO3 film having a thickness of 10 nm was formed on the photoelectric conversion layer by a vacuum deposition method through a metal mask, and then an Au film (second electrode layer) having a thickness of 100 nm was formed to form three element parts, thereby manufacturing a photodiode-type photodetection element.

### Comparative Example 2

A photodetection element of Comparative Example 2 was manufactured in the same method as in Example 1, except that in the step of forming the photoelectric conversion film, the InSb—(NH₄)₂S 2 was used instead of the InSb—InBr₃ dispersion liquid 1.

### <Evaluation of Photodetection Elements of Examples 1 to 4 and Comparative Examples 1 and 2>

Regarding the produced photodetection element, the dark current and external quantum efficiency (EQE) of the semiconductor film were evaluated by using a semiconductor parameter analyzer (C4156, manufactured by Agilent Technologies, Inc.).

First, the current-voltage characteristics (I-V characteristics) were measured while sweeping the voltage from 0 V to −2 V in a state of not carrying out irradiation with light, and the dark current was evaluated. Here, the current value at −0.5 V was defined as the dark current value. Subsequently, the I-V characteristics were measured while sweeping the voltage from 0 V to −2 V in a state of carrying out irradiation with monochromatic light (irradiation amount: 50 W/cm²) of 1,200 nm. A value obtained by subtracting the dark current value from the current value in a state where −0.5 V was applied was defined as the photocurrent value, and the external quantum efficiency (EQE) was calculated from the photocurrent value. It is noted that the numerical values described in the columns of the external quantum efficiency (EQE) and the dark current described in the table below are values of the central one element among the three element parts.

In addition, regarding the in-plane uniformity of the external quantum efficiency (EQE), the external quantum efficiency of each of the three element parts was measured, a value obtained by dividing a difference between the value of the highest external quantum efficiency and the value of the lowest external quantum efficiency by the external quantum efficiency of the element having the performance of the median value was calculated as ΔEQE, and the in-plane uniformity of the external quantum efficiency was evaluated based on ΔEQE. It means that the smaller the value of ΔEQE, the better the in-plane uniformity.

$$Δ E Q E ( \% ) = ( value of highest external quantum efficiency - value of lowest external quantum efficiency ) / medium value of external quantum efficiency \times 100$$

TABLE 3

| | Photoelectric conversion layer | | | | |
|---|---|---|---|---|---|
| | Kind of semiconductor | | EQE | Dark current | ΔEQE |
| | quantum dot | Ligand | (%) | (A/cm²) | (%) |
| Example 1 | InSb quantum dot 1 | InBr₃ | 8.4 | 2.6 × 10⁻⁶ | 10.7 |
| Example 2 | InSb quantum dot 2 | InBr₃ | 9.1 | 3.1 × 10⁻⁶ | 8.8 |
| Example 3 | InSb quantum dot 3 | InBr₃ | 10.3 | 2.9 × 10⁻⁶ | 9.7 |
| Example 4 | InSb quantum dot 1 | (NH₄)₂S | 3.5 | 4.1 × 10⁻⁶ | 19.1 |
| Comparative | InSb quantum dot C1 | Na₂S + NaN₃ | 0.5 | 2.2 × 10⁻⁶ | 144.9 |
| Example 1 | | | | | |
| Comparative | InSb quantum dot C1 | (NH₄)₂S | 0.8 | 3.7 × 10⁻⁶ | 98.8 |
| Example 2 | | | | | |

As shown in the above table, the photodetection element of Examples had a low dark current, and further, had a high external quantum efficiency (EQE) and excellent in-plane uniformity (ΔEQE) of the external quantum efficiency as compared with the photodetection element of Comparative Examples.

In a case of producing an image sensor using the photodetection element obtained in Examples by using an optical filter produced according to the method described in WO2016/186050A and WO2016/190162A and by a publicly known method and together with a publicly known method, it is possible to obtain an image sensor having good visibility and infrared imaging performance.

### EXPLANATION OF REFERENCES

1: photodetection element
11: first electrode layer
12: second electrode layer
13: photoelectric conversion layer
21: electron transport layer
22: hole transport layer

What is claimed is:

1. A semiconductor film comprising:
an aggregate of semiconductor quantum dots that contain an In element and a Group 15 element; and
a ligand that is coordinated to the semiconductor quantum dot,
wherein the Group 15 element includes an Sb element, and
a ratio of the number of the In elements to the number of the Group 15 elements in the semiconductor quantum dot is 1.1 or more.

2. The semiconductor film according to claim 1,
wherein the ratio of the number of the In elements to the number of the Group 15 elements in the semiconductor quantum dot is 1.5 or more.

3. The semiconductor film according to claim 1,
wherein the ratio of the number of the In elements to the number of the Group 15 elements in the semiconductor quantum dot is 2.0 or more.

4. The semiconductor film according to claim 1,
wherein the ligand includes an inorganic ligand.

5. The semiconductor film according to claim 4,
wherein the inorganic ligand includes an inorganic ligand containing a halogen element.

6. The semiconductor film according to claim 4,
wherein the inorganic ligand includes an inorganic ligand containing an In element.

7. The semiconductor film according to claim 1,
wherein a band gap of the semiconductor quantum dot is 1.0 eV or less.

8. A photodetection element comprising:
the semiconductor film according to claim 1.

9. An image sensor comprising:
the photodetection element according to claim 8.

10. A manufacturing method for a semiconductor quantum dot, the semiconductor quantum dot containing an In element and a Group 15 element, where the Group 15 element includes an Sb element, and a ratio of the number of the In elements to the number of the Group 15 elements in the semiconductor quantum dot is 1.1 or more, the manufacturing method for a quantum dot film, comprising:
a step of heating, at 290° C. or lower for 16 minutes or more, a precursor solution that contains a compound A containing an In element and a compound B containing an Sb element, where a molar ratio of the In element to the Sb element is 2.1 or more.
